(19) United States
(12) Patent Application Publication
(10) Pub. No.: US 2025/0063667 A1
(43) Pub. Date: Feb. 20, 2025

(54) ELECTRONIC ASSEMBLY AND MANUFACTURING METHOD THEREOF

(71) Applicant: ASUSTeK COMPUTER INC., Taipei City (TW)

(72) Inventors: Chih-Kuan Liu, Taipei City (TW); Xu Wang, Taipei City (TW)

(73) Assignee: ASUSTeK COMPUTER INC., Taipei City (TW)

(21) Appl. No.: 18/757,425

(22) Filed: Jun. 27, 2024

(30) Foreign Application Priority Data
Aug. 18, 2023 (TW) 112131147

(51) Int. Cl. H05K 1/18; H05K 1/02; H05K 3/22

(52) U.S. Cl. CPC H05K 1/185; H05K 1/0203; H05K 3/22; H05K 2201/066

(57) ABSTRACT

An electronic assembly includes a substrate, a chip configured on the substrate, a cover component configured on the chip, a capacitance element configured on the substrate, and a sealing structure surrounding the chip and sealing a gap between the cover component and the substrate. The sealing structure includes an insulating gel encapsulating the capacitance element. In addition, a manufacturing method of the electronic assembly is also provided.

### CROSS-REFERENCE TO RELATED APPLICATION

This application claims the priority benefit of Taiwan application serial no. 112131147, filed on Aug. 18, 2023. The entirety of the above-mentioned patent application is hereby incorporated by reference herein and made a part of this specification.

### BACKGROUND

### Technical Field

The disclosure relates to an electronic assembly and a manufacturing method thereof.

### Description of Related Art

A gap between a chip and a heat dissipation fin group may be filled with liquid metal, so that heat of the chip may be effectively transferred to the heat dissipation fin group. In order to prevent an overflow of liquid metal from causing a short circuit of a capacitance element adjacent to the chip and/or a short circuit of other elements in the electronic system, an insulating film, a foam, and a plastic cover are generally used to seal around the chip. However, the process of such a sealing method is complicated and is not easy to rework, and the prevention effect on the overflow of liquid metal is limited.

### SUMMARY

The disclosure provides an electronic assembly, which includes a substrate, a chip configured on the substrate, a cover component configured on the chip, a capacitance element configured on the substrate, and a sealing structure surrounding the chip and sealing a gap between the cover component and the substrate. The sealing structure includes an insulating gel encapsulating the capacitance element.

The disclosure further provides a manufacturing method of an electronic assembly, which includes the following steps. A substrate is provided in which a chip and a capacitance element are provided on the substrate. A sealing structure is provided on the substrate to surround the chip. A cover component is configured on the chip, and a gap between the cover component and the substrate is sealed by the sealing structure. The sealing structure includes an insulating gel. The step of providing the sealing structure includes the following steps. The capacitance element is encapsulated by the insulating gel. A shape of the insulating gel is defined by a jig and the insulating gel is cured.

Based on the above, the sealing structure of the disclosure includes the insulating gel for encapsulating the capacitance element, which may effectively prevent the overflowing liquid metal from causing a short circuit of the capacitance element. Moreover, in the disclosure, the insulating gel is used to encapsulate the capacitance element, so that the complex sealing structure of the insulating film and the plastic cover used to protect the capacitance element in the traditional sealing structure may be replaced, thereby simplifying the installation process of the sealing structure.

### BRIEF DESCRIPTION OF THE DRAWINGS

FIG. 1 is a partial cross-sectional view of an electronic assembly according to an embodiment of the disclosure.

FIG. 2 is a schematic top view of some elements of the electronic assembly of FIG. 1.

FIG. 3A to FIG. 3F are flowcharts of a manufacturing method of an electronic assembly according to an embodiment of the disclosure.

### DESCRIPTION OF THE EMBODIMENTS

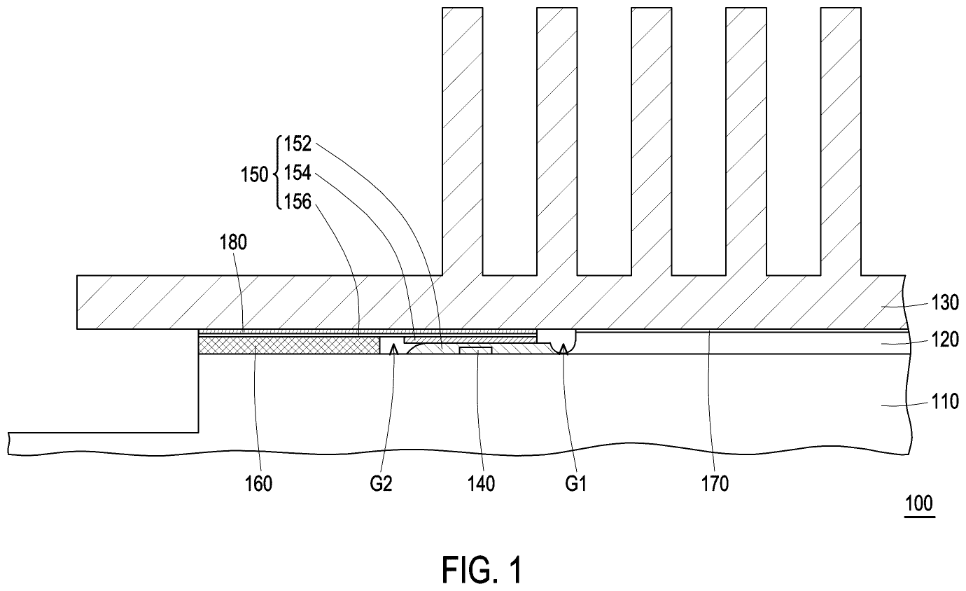

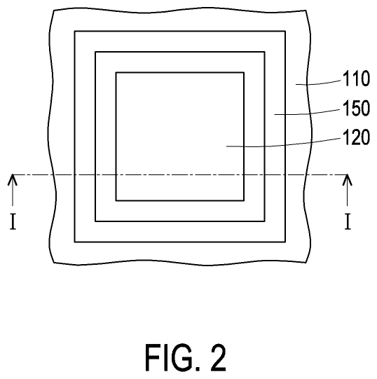

FIG. 1 is a partial cross-sectional view of an electronic assembly according to an embodiment of the disclosure. FIG. 2 is a schematic top view of some elements of the electronic assembly of FIG. 1. The cross-section of FIG. 1 corresponds to a part of line I-I of FIG. 2, for example. Please refer to FIG. 1 and FIG. 2. An electronic assembly 100 of the embodiment includes a substrate 110, a chip 120, a cover component 130, a capacitance element 140, a sealing structure 150, a structure reinforcing component 160, and a liquid metal layer 170. The chip 120 is, for example, a graphic processing unit (GPU) or other types of chips and is configured on the substrate 110. The cover component 130 is, for example, a heat sink (such as a heat dissipation fin group) and is configured on the chip 120. In other embodiments, the cover component 130 may be other types of elements, and the disclosure is not limited thereto.

The structure reinforcing component 160 is, for example, a ring-shaped metal component, which surrounds the chip 120 and is supported between the substrate 110 and the cover component 130. The liquid metal layer 170 is configured between the chip 120 and the cover component 130 to fill a gap between the chip 120 and the cover component 130. The capacitance element 140 is, for example, a multi-layer ceramic capacitor (MLCC) or other types of capacitors and is configured on the substrate 110. The sealing structure 150 surrounds the chip 120 and seals a gap between the cover component 130 and the substrate 110.

The sealing structure 150 of the embodiment includes an insulating gel 152 located between the chip 120 and the structure reinforcing component 160 and encapsulating the capacitance element 140. Accordingly, the protection of the capacitance element 140 by the insulating gel 152 may effectively prevent the overflowing liquid metal 170 from causing a short circuit of the capacitance element 140. Moreover, in the embodiment, the insulating gel 152 is used to encapsulate the capacitance element, so that the complex sealing structure of the insulating film and the plastic cover used to protect the capacitance element in the traditional sealing structure may be replaced, thereby simplifying the installation process of the sealing structure 150.

The insulating gel 152 in the embodiment is, for example, a removable gel so that it may be easy for the sealing structure 150 to rework. Moreover, the insulating gel 152 of the embodiment is, for example, a light-curable gel. Specifically, the insulating gel 152 of the embodiment may be a removable UV epoxy. However, the disclosure is not limited thereto, and in other embodiments, the insulating gel 152 may be a heat-curable gel or other kinds of gel.

Please refer to FIG. 1. In detail, the sealing structure 150 of the embodiment further includes a foam layer 154 and an insulating film 156. The foam layer 154 is configured between the insulating gel 152 and the cover component 130. The insulating film 156 is, for example, a polyimide (PI) film or other types of insulating films and is configured between the foam layer 154 and the cover component 130. The foam layer 154 has favorable elastic deformation ability to absorb manufacturing and assembly tolerances of the electronic assembly 100, so that the sealing structure 150 may reliably seal the gap between the cover component 130 and the substrate 110. The insulating film 156 has favorable heat resistance and is insulated between the foam layer 154 and the cover component 130 to prevent the heat of the chip 120 from passing through the cover component 130 directly to the foam layer 154 which has relatively insufficient heat resistance.

In the embodiment, the insulating film 156 is glued to the cover component 130 through a glue layer 180, for example. In addition, the foam layer 154 and the insulating film 156 may also be bonded to each other by a glue layer. However, the disclosure is not limited thereto, and there may not be a glue layer between the foam layer 154 and the insulating film 156.

As shown in FIG. 1, a groove G1 is formed between the insulating gel 152 and the chip 120, and another groove G2 is formed between the insulating gel 152 and the structure reinforcing component 160. Accordingly, the overflowing liquid metal layer 170 may be accommodated in the grooves G1 and G2, thereby effectively reducing the possibility of the liquid metal layer 170 continuing to overflow and causing short circuits in other elements in the electronic system.

The electronic assembly 100 of FIG. 1 is taken as an example below to describe a manufacturing method of an electronic assembly according to an embodiment of the disclosure.

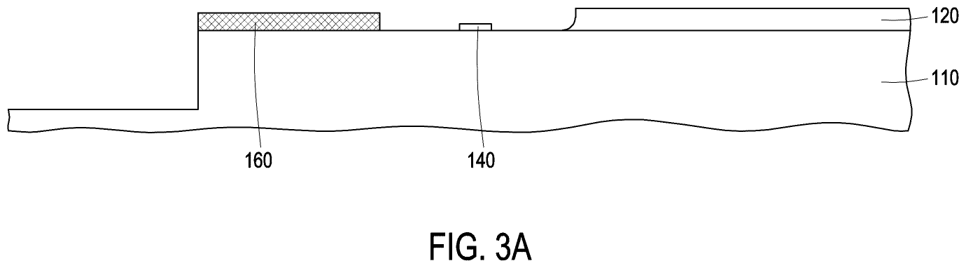

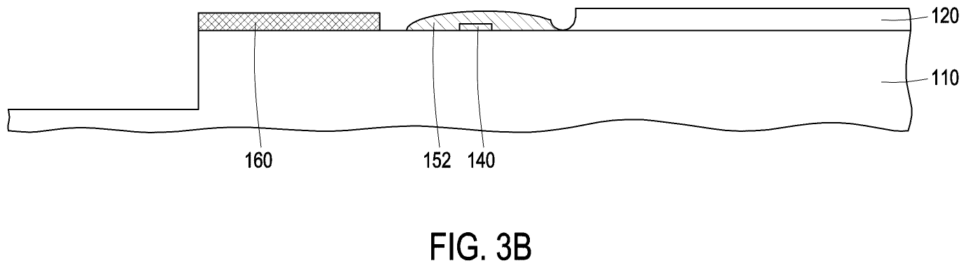

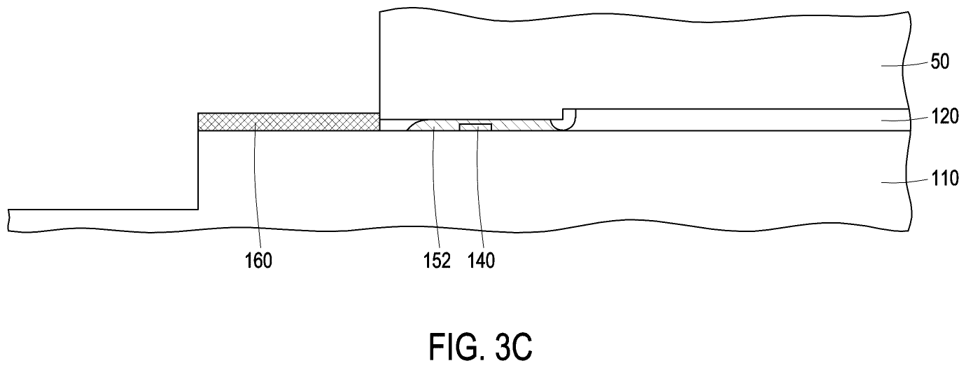

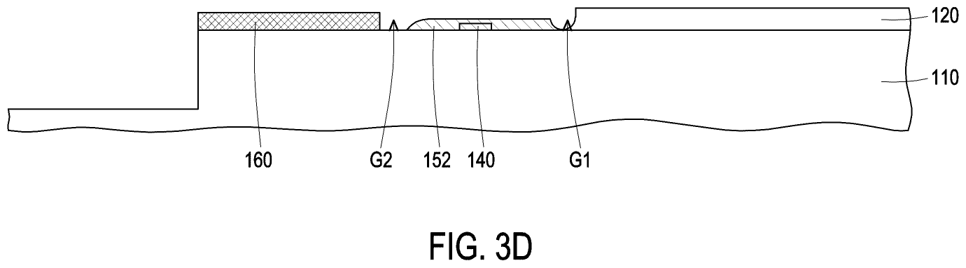

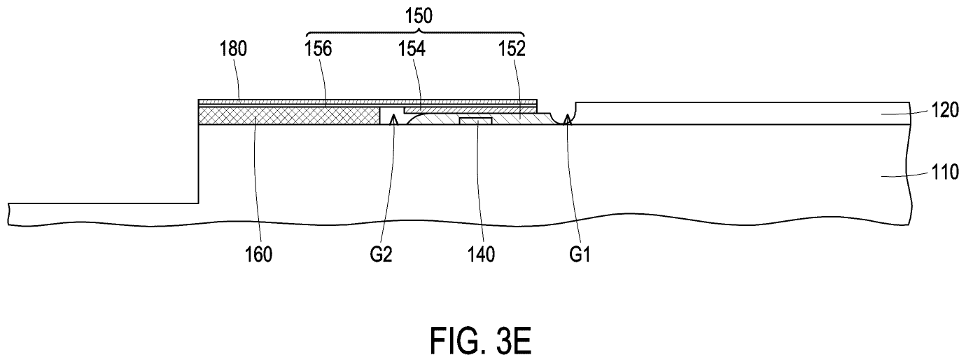

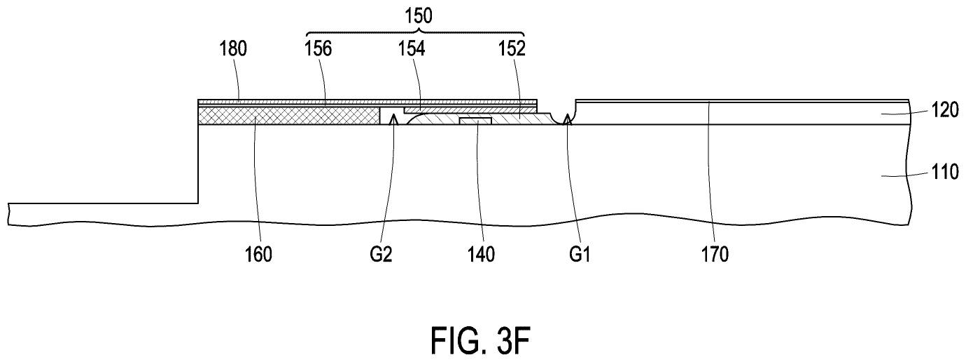

FIG. 3A to FIG. 3F are flowcharts of a manufacturing method of an electronic assembly according to an embodiment of the disclosure. First, as shown in FIG. 3A, the substrate 110 is provided. The chip 120, the capacitance element 140, and the structure reinforcing component 160 are provided on the substrate 110. The chip 120, the capacitance element 140, and the structure reinforcing component 160 are bonded to the substrate 110 through surface mounting technology (SMT), for example. Next, as shown in FIG. 3B to FIG. 3E, the sealing structure 150 is provided on the substrate 110 to surround the chip 120.

In detail, the steps of providing the sealing structure 150 are as follows. First, as shown in FIG. 3B, the insulating gel 152 is sprayed on the substrate 110 to make the insulating gel 152 be located at the capacitance element 140 between the chip 120 and the structure reinforcing component 160, so that the insulating gel 152 may encapsulate the capacitance element 140. Next, as shown in FIG. 3C, a shape of the insulating gel 152 is defined by a jig 50 and the insulating gel 152 is cured. The material of the jig 50 may be glass, and the method of curing the insulating gel 152 is, for example, light curing, heat curing, or other curing methods. So far, the groove G1 has been formed between the insulating gel 152 and the chip 120, and the groove G2 has been formed between the insulating gel 152 and the structure reinforcing component 160. The jig 50 is removed as shown in FIG. 3D. As shown in FIG. 3E, the foam layer 154 is configured on the insulating gel 152, and the insulating film 156 is configured on the foam layer 154. Specifically, for example, the pre-combined foam layer 154, insulating film 156, and glue layer 180 are configured on the insulating gel 152 and the structure reinforcing component 160 using the same process.

Then, the liquid metal layer 170 is configured on the chip 120 as shown in FIG. 3F. Next, the cover component 130 (shown in FIG. 1) is configured on the chip 120, so that the structure reinforcing component 160 is supported between the substrate 110 and the cover component 130, and the sealing structure 150 seals the gap between the cover component 130 and the substrate 110 to complete the electronic assembly 100 as shown in FIG. 1.

By using the jig 50 as above to shape the uncured insulating gel 152, it may accurately define the shape and size of the insulating gel 152, so that the insulating gel 152 may reliably encapsulate the capacitance element 140 and be accurately used with the foam layer 154 and the insulating film 156 to seal the gap between the cover component 130 and the substrate 110.

To sum up, the sealing structure of the disclosure includes the insulating gel for encapsulating the capacitance element, which may effectively prevent the overflowing liquid metal from causing a short circuit of the capacitance element. Moreover, in the disclosure, the insulating gel is used to encapsulate the capacitance element, so that the complex sealing structure of the insulating film and the plastic cover used to protect the capacitance element in the traditional sealing structure may be replaced, thereby simplifying the installation process of the sealing structure. In addition, the insulating gel may be a removable gel, so that it may be easy for the sealing structure to rework.

What is claimed is:

1. An electronic assembly, comprising:
a substrate;
a chip, configured on the substrate;
a cover component, configured on the chip;
a capacitance element, configured on the substrate; and
a sealing structure, surrounding the chip, and sealing a gap between the cover component and the substrate, wherein the sealing structure comprises an insulating gel, and the insulating gel encapsulates the capacitance element.

2. The electronic assembly according to claim 1, wherein the sealing structure further comprises a foam layer, and the foam layer is configured between the insulating gel and the cover component.

3. The electronic assembly according to claim 2, wherein the sealing structure further comprises an insulating film, and the insulating film is configured between the foam layer and the cover component.

4. The electronic assembly according to claim 1, wherein a groove is formed between the insulating gel and the chip.

5. The electronic assembly according to claim 1, further comprising a structure reinforcing component, wherein the structure reinforcing component is supported between the substrate and the cover component, and the insulating gel is located between the chip and the structure reinforcing component.

6. The electronic assembly according to claim 5, wherein a groove is formed between the insulating gel and the structure reinforcing component.

7. The electronic assembly according to claim 1, further comprising a liquid metal layer, wherein the liquid metal layer is configured between the chip and the cover component.

8. The electronic assembly according to claim 1, wherein the insulating gel is a light-curable gel or a heat-curable gel.

9. The electronic assembly according to claim 1, wherein the cover component is a heat sink.

10. The electronic assembly according to claim 1, wherein the insulating gel is a removable gel.

11. A manufacturing method of an electronic assembly, comprising:
providing a substrate, wherein a chip and a capacitance element are provided on the substrate;
providing a sealing structure on the substrate to surround the chip; and
configuring a cover component on the chip, so that the sealing structure seals a gap between the cover component and the substrate,
wherein the sealing structure comprises an insulating gel, and the step of providing the sealing structure comprises:
encapsulating the capacitance element using the insulating gel; and
defining a shape of the insulating gel by a jig and curing the insulating gel.

12. The manufacturing method of the electronic assembly according to claim 11, wherein the sealing structure further comprises a foam layer, and the step of providing the sealing structure further comprises:
configuring the foam layer on the insulating gel.

13. The manufacturing method of the electronic assembly according to claim 12, wherein the sealing structure further comprises an insulating film, and the step of providing the sealing structure further comprises:
configuring the insulating film on the foam layer.

14. The manufacturing method of the electronic assembly according to claim 11, further comprising:
forming a groove between the insulating gel and the chip.

15. The manufacturing method of the electronic assembly according to claim 11, wherein a structure reinforcing component is provided on the substrate, and the manufacturing method further comprises:
supporting the structure reinforcing component to be between the substrate and the cover component, and making the insulating gel be located between the chip and the structure reinforcing component.

16. The manufacturing method of the electronic assembly according to claim 15, further comprising:
forming a groove between the insulating gel and the structure reinforcing component.

17. The manufacturing method of the electronic assembly according to claim 11, further comprising:
configuring a liquid metal layer on the chip, before configuring the cover component on the chip.

18. The manufacturing method of the electronic assembly according to claim 11, wherein the step of curing the insulating gel comprises:
light curing the insulating gel or heat curing the insulating gel.

19. The manufacturing method of the electronic assembly according to claim 11, wherein the cover component is a heat sink.

20. The manufacturing method of the electronic assembly according to claim 11, wherein the insulating gel is a removable gel.
